(19) United States
(12) Patent Application Publication
(10) Pub. No.: US 2011/0169158 A1
(43) Pub. Date: Jul. 14, 2011

(54) Solder Pillars in Flip Chip Assembly

(75) Inventor: Arun K. Varanasi, San Diego, CA (US)

(73) Assignee: QUALCOMM INCORPORATED, San Diego, CA (US)

(21) Appl. No.: 12/687,268

(22) Filed: Jan. 14, 2010

(51) Int. Cl. H01L 23/488; H01L 23/48; H01L 21/60

(52) U.S. Cl. 257/692; 438/121; 257/738; 257/778; 257/779; 257/E21.509; 257/E23.023; 257/E23.01

(57) ABSTRACT

A semiconductor packaging system includes a semiconductor die and a solder pillar on a side of the semiconductor die extending outwardly from a side of the semiconductor die. The solder pillar electrically couples to an electrical contact of a packaging substrate, even when access to the electrical contact is limited by a mask.

### TECHNICAL FIELD

The present description generally relates to flip chip assembly and, more specifically, to the use of new shapes for portions of solder material.

### BACKGROUND

Flip chip assembly is a process in use today for integrated circuit (IC) packaging. A semiconductor die is created with metallized contact pads on a surface of the die. A mask is then laid down and solder is plated over the mask. The mask is removed and small solder balls are then formed on the metallized contact pads by reflowing the solder material. Depending on the process, the die is then cut and flipped over so the solder balls align with metal contacts on a packaging substrate. The die is placed on the packaging substrate, and the solder is then reflowed to ensure that the solder makes sufficient electrical contact with the metal contacts on the packaging substrate. Insulating underfill is then applied to the package. The result is a semiconductor package where the inputs and outputs of the die are in electrical communication with the packaging substrate. An overall system may have other components thereon, such as processors, passive components, power components, and the like, which are then interfaced with the semiconductor die through, for example, traces on the package.

FIG. 1 illustrates a conventional assembly technique employing solder balls. A semiconductor die 101 includes a metallized contact pad 102, which is in contact with a solder ball 103 (also known as a “flip chip bump”). A package substrate 104 includes a copper contact 105 and the mask 106. As seen in FIG. 1, the mask 106 prevents the solder ball 103 from making electrical contact with the copper contact 105, even after the solder ball 103 is reflowed. FIG. 1 illustrates a defect that happens from time to time during flip chip techniques that use solder balls. Such a lack of contact is sometimes caused by a shift in solder mask registration or other kind of misalignment.

Currently there are two solutions available, one of which is shown in FIG. 2. The assembly technique of FIG. 2 includes filling the solder mask opening of the package substrate 104 with the solder 107 to facilitate contact with the solder ball 103. The assembly technique is known as solder on pad (SOP). The SOP technique has several disadvantages. SOP is relatively hard to control for both coplanarity and quality. SOP involves an additional thermal cycle, and precautions are necessary to maintain surface quality for good solder attachment. Furthermore, in practice, current SOP processes can only be used for pitches of 150 μm and larger.

Another solution uses copper posts, as shown in FIG. 3. FIG. 3 shows a process that uses a copper post 301 and a solder cap 302 to make electrical contact between the copper contact 105 and the semiconductor die 101. The copper post technique of FIG. 3 has several disadvantages, as well. For instance, the copper post technique is relatively expensive when compared to the technique of FIGS. 1 and 2. Furthermore, copper is quite rigid, and some materials within the semiconductor die 101 are somewhat brittle, so that when stress is applied to the assembly, the semiconductor die 101 can be mechanically damaged.

### BRIEF SUMMARY

According to one embodiment, a semiconductor package system includes a semiconductor die and a solder pillar on a side of the semiconductor die extending outwardly from a side of the semiconductor die.

According to another embodiment, a method for packaging a semiconductor die includes disposing photo resist upon a die, the die having a first metal contact, and the photo resist defining a volume that is substantially pillar-shaped and aligned with the first metal contact. The method also includes providing solder material within the volume, reflowing the solder material within the volume, and removing the photo resist to expose the solder material.

According to yet another embodiment, a semiconductor die has multiple conductive pads, each of the conductive pads providing an interface to circuitry within the semiconductor die. The die also has means for facilitating electrical communication with contacts on a package substrate, each of the means for facilitating corresponding to, and in contact with, one of the conductive pads and having a pillar shape and being formed of solder material.

The foregoing has outlined rather broadly the features and technical advantages of the present invention in order that the detailed description that follows may be better understood. Additional features and advantages will be described hereinafter which form the subject of the claims of the invention. It should be appreciated by those skilled in the art that the conception and specific embodiments disclosed may be readily utilized as a basis for modifying or designing other structures for carrying out the same purposes of the present invention. It should also be realized by those skilled in the art that such equivalent constructions do not depart from the technology of the invention as set forth in the appended claims. The novel features which are believed to be characteristic of the invention, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present invention.

### BRIEF DESCRIPTION OF THE DRAWINGS

For a more complete understanding of the present disclosure, reference is now made to the following description taken in conjunction with the accompanying drawings.

FIG. 1 is a schematic illustrating a conventional assembly technique employing solder balls.

FIG. 2 is a schematic illustrating a conventional SOP assembly technique employing solder balls.

FIG. 3 is a schematic illustrating a conventional assembly technique employing copper posts.

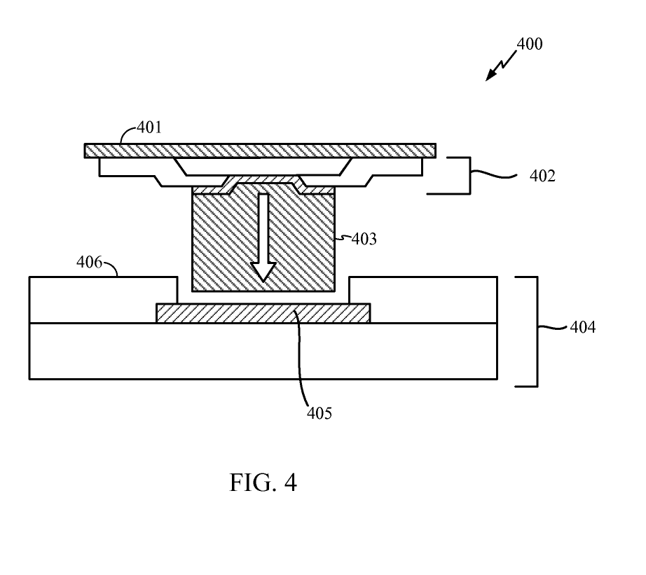

FIG. 4 is an illustration of an exemplary system adapted according to one embodiment of the disclosure.

FIGS. 5A and 5B are illustrations of an exemplary technique, according to one embodiment of the disclosure, for creating a cylindrical solder bump and making preliminary contact with a package substrate.

FIG. 6 is an illustration of three different basic shapes that can be used for solder pillars according to various embodiments.

FIG. 7 is a schematic illustrating an exemplary wireless communication system in which an embodiment may be advantageously employed.

### DETAILED DESCRIPTION

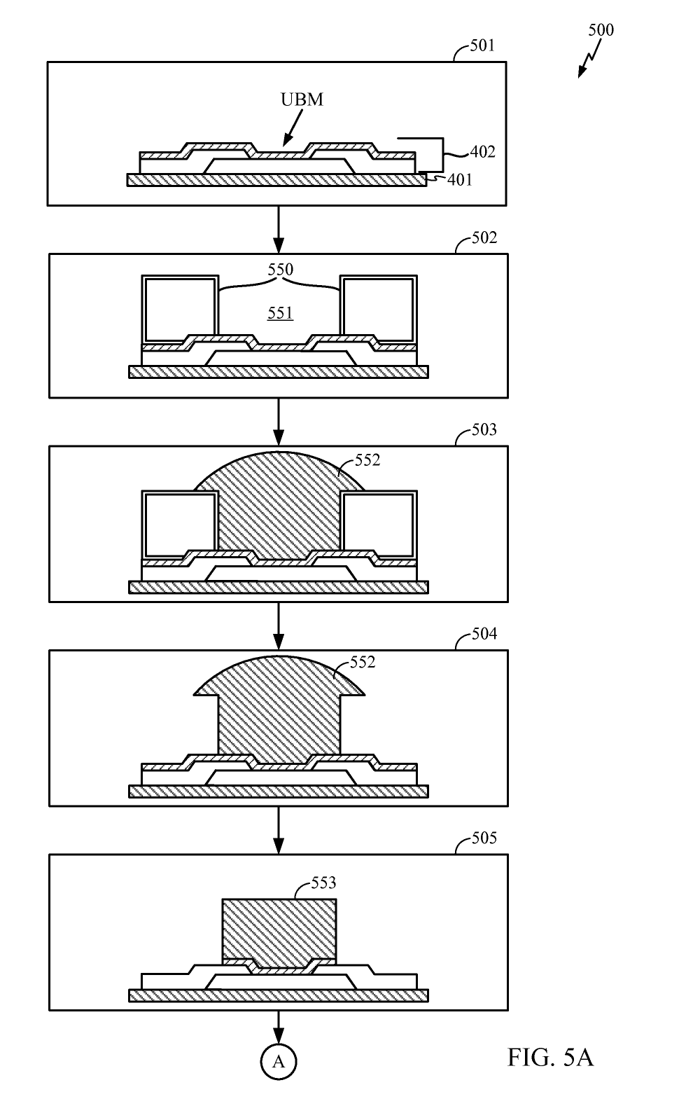

FIG. 4 is an illustration of an exemplary system 400 adapted according to one embodiment. The system 400 includes a semiconductor die 401 and under bump metallurgy (UMB) 402, which provides an electrical contact between the solder bump 403 and circuitry (not shown) within the die 401. While not shown in FIG. 4 for simplicity, it is understood that the solder bump 403 is aligned and moved relative to a metal contact 405 so as to make electrical contact therewith.

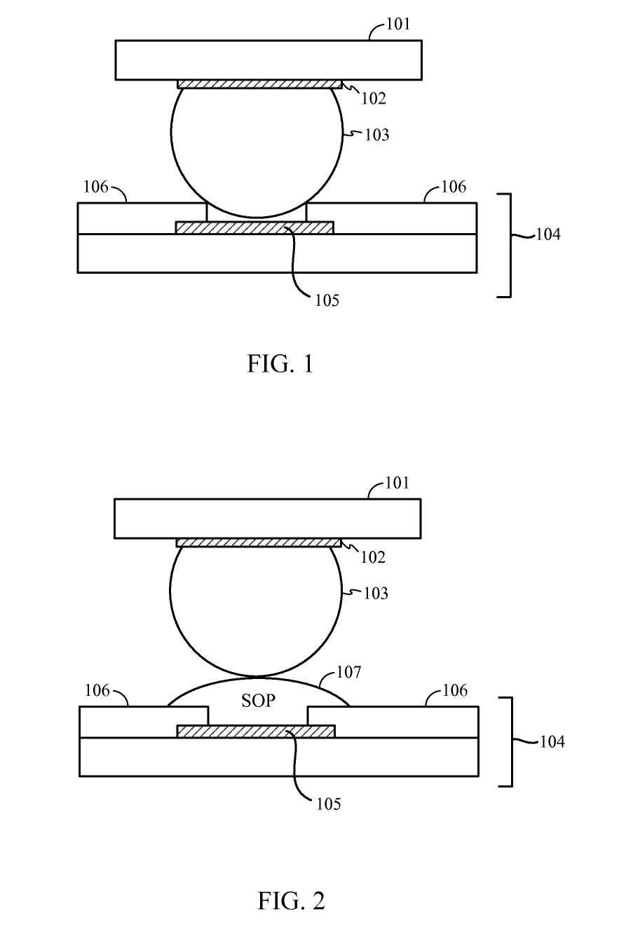

In the present example, the solder bump 403 is shaped substantially as a cylinder. That is, in this example, the solder bump 403 conforms to a basic cylinder shape but deviates from a true cylinder shape at the interface with the UBM 402. The circumference of the cylinder shape can be smaller than that of the solder ball of FIG. 1, while the elongated dimension allows for electrical contact to be made between the UBM 402 and the metal contact 405 of the package substrate 404. In short, the cylindrical shape of the solder bump 403 facilitates making preliminary contact with the metal contact 405 through the opening in the mask 406.

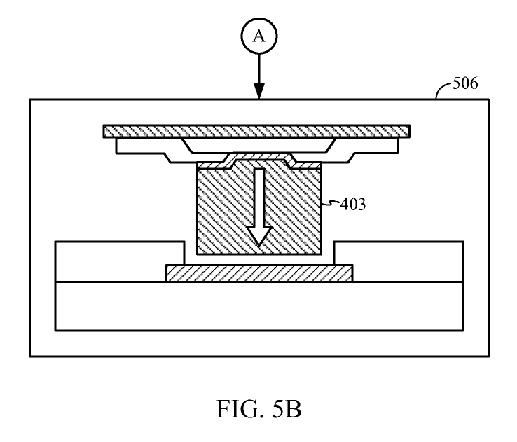

FIGS. 5A and 5B are illustrations of an exemplary technique 500 for creating a cylindrical solder bump and making preliminary contact with a package substrate. In block 501, the UBM 402 is created on the semiconductor die 401 by, e.g., sputtering. In an exemplary embodiment, the die pad may be coated with the UBM. The UBM 402 creates an electrical interface with circuitry inside of the semiconductor die 401.

In block 502, photo resist is applied in a pattern to create a mask 550. In block 502, the view of the photo resist is a cut-away view, and it is understood that the photo resist creates a substantially cylindrical volume 551. The technique uses the pattern of the mask 550 to provide the shape of the solder bump (as explained in more detail below). Any of a variety of materials, such as color photoresists, can be used to create the mask 550. In one particular example, polyamide is used as a material for the mask 550 because its relatively high heat resistance allows for a reflow process to be performed before the mask 550 has been removed (as explained below with respect to the block 504).

In block 503, the solder material 552 is applied. In one example, the solder is plated as a eutectic mixture on the mask 550. The mask 550 allows the solder material 552 into the volume 551, thereby creating a cylindrical shape with a cap on top.

Further in block 503, the solder material 552 is reflowed. For instance, the structure can be heated beyond the melting point of the solder but not so high as to melt or char the mask 550 or the die 401. Reflowing after plating is used in this embodiment to cause the different layers of solder material to coalesce. In some embodiments, a reflow profile is used, wherein the structure is slowly heated up and cooled down. The solder material 552 is constrained by boundaries of the volume 551, and the shape of the eventual solder bump is dictated, at least in part, by the shape of the volume 551.

In block 504, the mask 550 is removed after the solder material 552 has returned to a solid state. Any of a variety of techniques can be used to remove the mask 550, such as, for example, stripping the mask 550 with a solvent, e.g., acetone.

In block 505 buffing is performed to make a distal surface 553 substantially flat. Thus, in this example, the shape of the solder bump 403 is defined by the mask pattern, the plating process, and the buffing process. Buffing can be used to achieve a greater degree of coplanarity than could be achieved otherwise. In this context, coplanarity refers to the property of the surface 553 as it relates spatially to similar surfaces of other solder bumps (not shown) on the die 401. In many embodiments, the distal surface 553 and similar surfaces of other solder bumps are substantially coplanar so that contact is made by all solder bumps to their respective package substrate contacts. For many applications, coplanarity on the order of a few microns is sufficient. Buffing, such as by chemical mechanical polishing, can be performed either before or after mask removal.

In block 506 (FIG. 5B), the structure that includes the die 401 and the solder bump 403 is brought into proximity with the package substrate 404 and aligned with the metal contact 405. In block 506, some embodiments (as seen in FIG. 5B) include flipping the structure that includes the die 401 and the solder bump 403 so that it is spatially located above the package substrate 404. Preliminary contact is made between the solder bump 403 and the metal contact 405, for example by solder reflow.

While the technique 500 is shown as a series of specific processes, various embodiments are not limited thereto. In fact, other embodiments may add, omit, modify, or rearrange various processes. For instance, after the block 506, some embodiments perform an additional reflow process followed by an underfill process. The resulting package substrate assembly, including the die 401, can be used in further manufacturing processing, such as disposing other components onto the package substrate 404 and installing the package substrate assembly in a device (e.g., a mobile device or other processor-based device). Furthermore, while the technique is illustrated with respect to a single solder bump 403, it is noted that many embodiments will perform the technique for a multitude of solder bumps on a die (e.g., 800 solder bumps). Furthermore, while the embodiments above have been described with reference made to specific materials for the mask and the solder bump, it is noted that various embodiments may use any suitable solder or mask material.

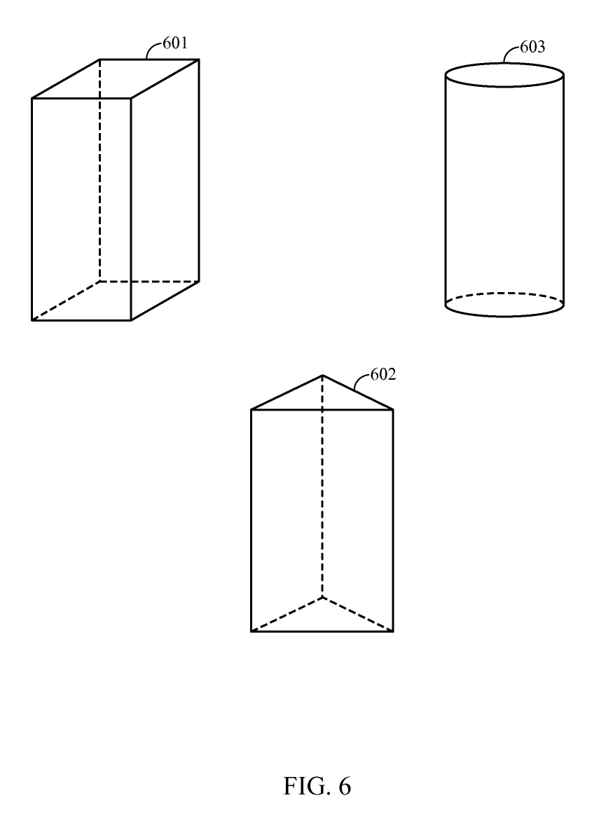

Additionally, while solder pillars have been shown above as substantially cylindrical in shape, other embodiments may include pillars of different geometries. FIG. 6 is an illustration of three different basic shapes that can be used for solder pillars according to various embodiments, and FIG. 6 is intended to be non-exclusive. FIG. 6 includes a rectangular volume 601, a triangular volume 602, and a cylindrical volume 603, though a variety of arbitrary shapes, such as octagonal volumes, are adaptable to various embodiments.

Various embodiments of the invention provide advantages over prior art solutions. For instance, some embodiments offer more control of the structure than was provided with solder balls. The diameter of the pillar can be adjusted to easily fit within the aperture provided by the mask on the package substrate. In fact, the diameter of the column can be adjusted to compensate for alignment tolerance, thereby helping to ensure contact with the metal pad. Also, solder pillars offer the alignment benefits of copper posts while avoiding the rigidity of copper posts that can lead to damage to the semiconductor die when stress is applied to the structure.

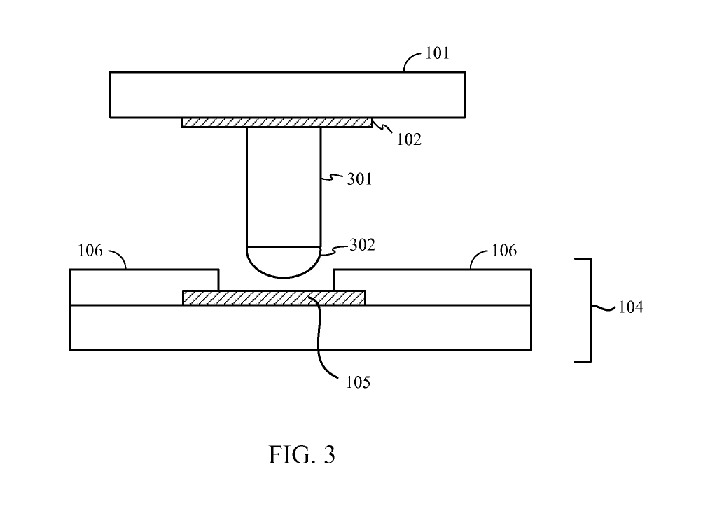

Furthermore, some embodiments offer better coplanarity than the SOP solution shown in FIG. 2, especially when buffing or another shaping process is performed on the pillars. Coplanarity generally becomes a greater issue as the number of bumps and contacts increases, and greater coplanarity can help increase yield.

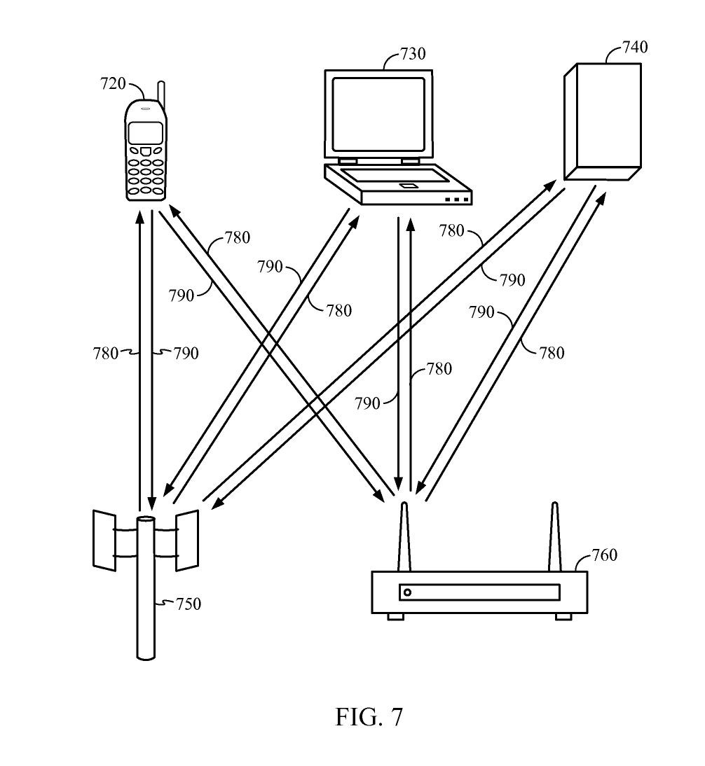

FIG. 7 shows an exemplary wireless communication system 700 in which an embodiment of the invention may be advantageously employed. For purposes of illustration, FIG. 7 shows three remote units 720, 730, and 740 and two base stations 750, 760. It will be recognized that wireless communication systems may have many more remote units and base stations. The remote units 720, 730, and 740 and the base stations 750, 760 can include any of a variety of components, such as memory units, Analog to Digital Converters (ADCs), Digital to Analog Converters (DACs), processors, delta sigma data converters, and the like (and the components can be manufactured from semiconductor dies such as the die 401 of FIGS. 4 and 5). Embodiments can utilize package assemblies that include components wherein the components have been mounted on the package assemblies using solder pillar techniques described above. FIG. 7 shows forward link signals 780 from the base stations 750, 760 to the remote units 720, 730, and 740 and the reverse link signals 790 from the remote units 720, 730, and 740 to the base stations 750, 760.

Generally, remote units may include cell phones, hand-held personal communication systems (PCS) units, portable data units such as personal data assistants, fixed location data units such as meter reading equipment, and/or the like. In FIG. 7, the remote unit 720 is shown as a mobile telephone, the remote unit 730 is shown as a portable computer, and the remote unit 740 is shown as a fixed location remote unit in a wireless local loop system. The base stations 750, 760 can be any of a variety of wireless base stations, including, e.g., cellular telephone base stations, wireless network access points (e.g., IEEE 802.11 compliant access points), and the like. Although FIG. 7 illustrates remote units and base stations, the disclosure is not limited to these exemplary illustrated units.

Although the present invention and its advantages have been described in detail, it should be understood that various changes, substitutions and alterations can be made herein without departing from the technology as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding embodiments described herein may be utilized. Accordingly, the appended claims are intended to include within their scope such processes, machines, manufacture, compositions of matter, means, methods, or steps.

What is claimed is:

1. A semiconductor package system, comprising:
a semiconductor die; and
a solder pillar on a side of the semiconductor die extending outwardly from the side of the semiconductor die.

2. The system of claim 1 wherein the solder pillar comprises a substantially cylindrical portion of solder material.

3. The system of claim 1 wherein the solder pillar comprises a substantially rectangular volume.

4. The system of claim 1 wherein a distal end of the solder pillar is substantially flat.

5. The system of claim 1 further comprising:
under bump metallurgy between the solder pillar and the semiconductor die.

6. The system of claim 1 further comprising:
a package substrate including a metal electrical contact, the solder pillar providing electrical communication between the semiconductor die and the metal electrical contact.

7. The system of claim 6, wherein the package substrate includes at least one circuit component in electrical communication with the metal electrical contact.

8. The system of claim 1 wherein the semiconductor die is selected from a list consisting of:
a processor;
an analog to digital converter;
a digital to analog converter; and
a digital signal processor.

9. A method for packaging a semiconductor die, the method comprising:
disposing photo resist upon the die, the photo resist defining a volume that is substantially pillar-shaped and coupled to a metal contact of the die;
providing solder material within the volume;
reflowing the solder material within the volume; and
removing the photo resist to expose the substantially pillar shaped solder material.

10. The method of claim 9 further comprising:
buffing the solder material to create a substantially flat distal surface.

11. The method of claim 10 wherein the buffing comprises:
making the distal surface of the solder material substantially coplanar with distal surfaces of a plurality of solder bumps on the die.

12. The method of claim 9 further comprising:
coupling the solder material and a metal contact on a package substrate.

13. The method of claim 12 further comprising:
reflowing the solder material.

14. The method of claim 13 further comprising:
providing underfill between the die and the package substrate.

15. The method of claim 14 further comprising:
installing a packaged die into an item selected from the list comprising:
a mobile device;
a music player;
a video player;
a personal digital assistant; and
a navigation device.

16. The method of claim 9 wherein the photo resist comprises polyamide.

17. A semiconductor die comprising:
a plurality of conductive pads, each of the conductive pads providing an interface to circuitry within the semiconductor die; and
means for facilitating electrical communication with contacts on a package substrate, each of the means for facilitating corresponding to, and coupled with, one of the conductive pads and having a pillar shape and being solder material.

18. The semiconductor die of claim 17 wherein each of the means for facilitating conforms substantially to a cylinder shape.

19. The semiconductor die of claim 17 comprising a microprocessor.

20. The semiconductor die of claim 17, wherein the means for facilitating are fabricated according to the following process:
disposing photo resist upon the semiconductor die, the photo resist defining a plurality of volumes that are substantially pillar-shaped and aligned with the plurality of conductive pads;
providing solder material within the volumes;
reflowing the solder material within the volumes; and
removing the photo resist to expose the solder material.
